(19) United States
(12) Patent Application Publication
(10) Pub. No.: US 2026/0050212 A1
(43) Pub. Date: Feb. 19, 2026

(54) RESIST TOPCOAT COMPOSITION AND METHOD OF FORMING PATTERNS USING THE COMPOSITION

(71) Applicant: SAMSUNG SDI CO., LTD., Yongin-si (KR)

(72) Inventors: Daeseok SONG, Suwon-si (KR); Ran NAMGUNG, Suwon-si (KR); Kyoungjin HA, Suwon-si (KR); Hyeon PARK, Suwon-si (KR); Minsoo KIM, Suwon-si (KR)

(21) Appl. No.: 19/258,022

(22) Filed: Jul. 2, 2025

(30) Foreign Application Priority Data
Aug. 13, 2024 (KR) 10-2024-0108178

(51) Int. Cl. G03F 7/004; C08K 5/095; C09D 133/14; G03F 7/095; G03F 7/11; G03F 7/16

(52) U.S. Cl. CPC G03F 7/0045; G03F 7/095; G03F 7/11; G03F 7/16; C08K 5/095; C09D 133/14

(57) ABSTRACT

A resist (e.g., photoresist) topcoat composition and a method of forming or providing patterns by utilizing the resist (e.g., photoresist) topcoat composition are disclosed. The resist (e.g., photoresist) topcoat composition may include an aromatic compound substituted with —I and —COOH, a polymer including a structural unit as represented by Chemical Formula M-1, and a solvent. The Chemical Formula is described in more detail in the present disclosure.

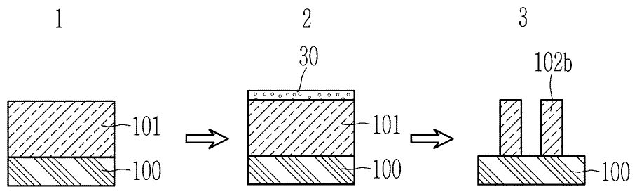

### CROSS-REFERENCE TO RELATED APPLICATION

The present application claims priority to and the benefit of Korean Patent Application No. 10-2024-0108178, filed on Aug. 13, 2024, in the Korean Intellectual Property Office, the entire disclosure of which is incorporated herein by reference.

### BACKGROUND

### 1. Field

One or more embodiments of the present disclosure relate to a resist (e.g., photoresist) topcoat composition and a method of forming or providing patterns by utilizing the resist (e.g., photoresist) topcoat composition.

### 2. Description of the Related Art

The semiconductor industry has developed an ultrafine technique having a pattern of several nanometers to several tens of nanometers in size. It is desirable for such ultrafine technique to be effective or suitable photolithographic processes.

The photolithographic processes involve forming or providing a material layer on a semiconductor substrate, coating a photoresist layer thereon, exposing and developing to form or provide a photoresist pattern, and then etching the material layer by utilizing the photoresist pattern as a mask.

As photolithography processes advance, a degree of pattern integration is increasing, and materials and technologies to solve one or more problems that occur in the processes are desired or required.

For example, if (e.g., when) extreme ultraviolet (EUV) is irradiated to a photoresist, because there may be a region where lots of or little light is randomly irradiated due to large energy per photon, which is a photon shot noise, or an EUV absorption difference between an upper portion and a lower portion of the photoresist may cause pattern dispersion deterioration, such as roughness (e.g., LER: line edge roughness and LWR: line width roughness) and/or IPU (in-point uniformity) of the patterns, in order to improve or enhance this pattern dispersion deterioration, technology development is desired or required.

### SUMMARY

One or more aspects of embodiments of the present disclosure are directed toward a resist (e.g., photoresist) topcoat composition which not only prevents pattern degradation (or reduces a degree or occurrence of pattern degradation) and reduces pattern dispersion degradation (or reduces a degree or occurrence of pattern dispersion degradation), but also improves or enhances the sensitivity (e.g., the sensitivity of the photoresist during the photolithography micropattern formation process (e.g., the sensitivity capable of forming or providing a critical dimension (CD) of 50 nm)).

One or more aspects of embodiments of the present disclosure are directed toward a method of forming or providing patterns by utilizing the resist topcoat composition.

Additional aspects of embodiments will be set forth in part in the description which follows and, in part, will be apparent from the description or may be learned by practice of the presented embodiments of the disclosure.

One or more embodiments of the present disclosure provide a resist topcoat composition including an aromatic compound substituted with an iodine atom (—I) and a carboxyl group (—COOH), a polymer including a structural unit as represented by Chemical Formula M-1, and a solvent.

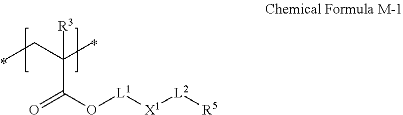

In Chemical Formula M-1,
R³ may be a hydrogen atom or a substituted or unsubstituted C1 to C10 alkyl group,
L¹ and L² may each independently be a single bond (e.g., a single covalent bond) or a substituted or unsubstituted C1 to C10 alkylene group,
X¹ may be a single bond (e.g., a single covalent bond), —O—, —S—, —S(═O)—, —S(═O)₂—, —C(═O)—, —C(═O)O—, —OC(═O)—, —OC(═O)O—, or —NR^{a}— (wherein, R^{a} may be a hydrogen atom, a deuterium atom, or a substituted or unsubstituted C1 to C10 alkyl group),
R⁵ may be a hydrogen atom, a fluorine atom, a hydroxyl group, or a substituted or unsubstituted C1 to C20 alkyl group,
at least one selected from among R⁵, L¹, and L² may include a fluorine atom and a hydroxyl group, and
* may be a linking point.

One or more embodiments of the present disclosure provide a method of forming or providing patterns which includes coating and heating a photoresist composition on a substrate to form or provide a photoresist layer, coating and heating the resist topcoat composition, as described in one or more embodiments of the present disclosure, on the photoresist layer to form or provide a topcoat, and exposing and developing the topcoat and the photoresist layer to form or provide a resist pattern.

According to one or more embodiments of the present disclosure, the resist topcoat composition may improve or enhance a profile of an upper portion of a photoresist pattern by capturing (or quenching) an acid on the surface of a photoresist if (e.g., when) exposed to EUV, thereby preventing deterioration (or reducing a degree or occurrence of deterioration) of pattern dispersion, such as LWR (line width roughness) and/or IPU (in-point uniformity) of the pattern, and being advantageously or beneficially utilized to form or provide a fine pattern of a photoresist.

### BRIEF DESCRIPTION OF THE DRAWING

The accompanying drawing, together with the specification, illustrates embodiments of the subject matter of the present disclosure, and, together with the description, serve to explain principles of embodiments of the subject matter of the present disclosure.

The accompanying drawing is a schematic view to illustrate a method of forming or providing patterns by utilizing a resist topcoat composition according to one or more embodiments of the present disclosure.

### DETAILED DESCRIPTION

Hereinafter, embodiments of the present disclosure will be described in more detail so that those skilled in the art can easily implement the present disclosure. However, the subject matter of the present disclosure may be embodied in one or more suitable forms and should not be construed as being limited to the embodiments set forth herein.

The terminology used herein is used to describe particular embodiments only and is not intended to be limiting of the present disclosure. The singular expression includes the plural expression unless the context clearly dictates otherwise.

As utilized herein, the singular forms “a,” “an,” and “the” are intended to include the plural forms as well, unless the context clearly indicates otherwise. Further, the utilization of “may” if (e.g., when) describing embodiments of the present disclosure refers to “one or more embodiments of the present disclosure.”

In the context of the present disclosure and unless otherwise defined, the terms “use”, “using”, and “used” may be considered synonymous with the terms “utilize”, “utilizing”, and “utilized”, respectively.

As utilized herein, the term “about” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and refers to within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, the applicant reserves the right to amend this specification, including the claims, to expressly recite any sub-range subsumed within the ranges expressly recited herein.

Herein, it should be understood that terms, such as “includes”, “including”, “have”, or “having”, are intended to designate the presence of an embodied feature, number, step, element, or a combination thereof, but it does not preclude the possibility of the presence or addition of one or more other features, number, step, element, or a combination thereof.

In the present disclosure, it will be understood that the term “comprise(s)/comprising”, “include(s)/including”, or “have/has/having” specifies the presence of stated features, integers, steps, operations, elements, and/or components, but do not preclude the presence or addition of one or more other features, integers, steps, operations, elements, components, and/or combination thereof. In one or more embodiments, the terms “comprise(s)/comprising”, “include(s)/including”, “have/has/having” or similar terms include or support the terms “consisting of” and “consisting essentially of”, indicating the presence of stated features, integers, steps, operations, elements, and/or components, without or essentially without the presence of other features, integers, steps, operations, elements, components, and/or combination thereof.

In the drawing, the thickness of layers, films, panels, regions, and/or the like may be exaggerated to effectively or suitably illustrate the technical contents of the present disclosure.

Like reference numerals designate like elements throughout the specification.

Herein, “or” is not to be construed as an exclusive meaning, for example, “A or B” is construed to include A, B, A+B, and/or the like.

It will be understood that if (e.g., when) an element, such as a layer, a film, a region, or a substrate, is referred to as being “on” another element, it may be directly on the other element or intervening elements may also be present therebetween. In contrast, if (e.g., when) an element is referred to as being “directly on” another element, there are no intervening elements present therebetween.

As used herein, if (e.g., when) a definition is not otherwise provided, “substituted” refers to replacement of at least one hydrogen atom of a substituent or a compound by a substituent selected from among a halogen atom (F, Br, Cl, or I), a hydroxyl group, a thiol group, a nitro group, a cyano group, an amino group, a substituted or unsubstituted C1 to C30 amine group, an azido group, an amidino group, a hydrazino group, a hydrazono group, a carbonyl group, a carbamyl group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C30 sulfide group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, or a C3 to C30 heterocycloalkyl group, and a combination thereof.

As used herein, if (e.g., when) a definition is not otherwise provided, “an alkyl group” refers to a linear or branched aliphatic hydrocarbon group. The alkyl group may be “a saturated alkyl group” without any double bond or triple bond.

The alkyl group may be a C1 to C20 alkyl group. For example, the alkyl group may be a C1 to C10 alkyl group or a C1 to C6 alkyl group. For example, the C1 to C5 alkyl group refers to that the alkyl chain contains 1 to 5 carbon atoms and is selected from among methyl, ethyl, propyl, iso-propyl, n-butyl, iso-butyl, sec-butyl, and tert-butyl.

The alkyl group refers to specific examples that are a methyl group, an ethyl group, a propyl group, an isopropyl group, a butyl group, an isobutyl group, a tert-butyl group, a pentyl group, a hexyl group, and/or the like.

In chemical formulas as described in one or more embodiments, t-Bu refers to a tert-butyl group.

As used herein, if (e.g., when) a definition is not otherwise provided, “cycloalkyl group” refers to a monovalent cyclic aliphatic hydrocarbon group.

The cycloalkyl group refers to a cyclopropyl group, a cyclobutyl group, a cyclopentyl group, a cyclohexyl group, and/or the like.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

As used herein, “aryl group” refers to a substituent in which all atoms in the cyclic substituent have a p-orbital, and these p-orbitals are conjugated and may include a monocyclic or fused ring polycyclic (e.g., rings that share adjacent pairs of carbon atoms) functional group.

As used herein, if (e.g., when) a definition is not otherwise provided, “hetero” refers to one including 1 to 3 heteroatoms selected from among nitrogen (N), oxygen (O), sulfur (S), selenium (Se), and phosphorus (P).

In the present disclosure, if (e.g., when) a definition is not otherwise provided, “heterocycloalkyl group” refers to a cycloalkyl group containing at least one hetero atom selected from among nitrogen (N), oxygen (O), sulfur (S), phosphorus (P), and silicon (Si).

In the present disclosure, “heteroaryl group” refers to an aryl group including at least one hetero atom selected from among N, O, S, P, and Si. Two or more heteroaryl groups are linked by a sigma bond directly, or if (e.g., when) the heteroaryl group includes two or more rings, the two or more rings may be fused. If (e.g., when) the heteroaryl group is a fused ring, each ring may include 1 to 3 hetero atoms.

Unless otherwise specified in the present disclosure, the weight average molecular weight (M_{w}) is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In one or more embodiments, unless otherwise defined in the specification, “*” indicates a linking point of a structural unit or a compound moiety of a compound.

Unless otherwise defined, all terms (including technical and scientific terms) used herein have substantially the same meaning as generally understood by one of ordinary skill in the art to which the present disclosure belongs. It will be further understood that terms, such as those defined in dictionaries that are generally available or generally used, should be interpreted as having a meaning that is consistent with their meaning in the context of the relevant art and will not be interpreted in an idealized or overly formal sense unless expressly so defined herein.

### Resist Topcoat Composition

Hereinafter, a resist (e.g., photoresist) topcoat composition according to one or more embodiments of the present disclosure is described.

One or more embodiments of the present disclosure relate to a photoresist topcoat composition and a method of forming or providing a photoresist pattern by utilizing the photoresist topcoat composition and the topcoat, which may improve or enhance the sensitivity of the photoresist during the photolithography micropattern formation process (e.g., the sensitivity capable of forming or providing a critical dimension (CD) of 50 nm) which utilizes high-energy rays, such as extreme ultraviolet (EUV; wavelength of 13.5 nm) and at the same time (e.g., concurrently) may selectively reduce an acid concentration in the upper layer of the photoresist, to improve or enhance in-point uniformity (IPU) of contact hole (C/H) patterns, line edge roughness (LER)/line width roughness (LWR) of line and space (L/S) patterns, and IPU of pillar patterns.

In one or more embodiments, a resist topcoat composition according to one or more embodiments of the present disclosure may include an aromatic compound substituted with —I and —COOH, a polymer including a structural unit as represented by Chemical Formula M-1, and a solvent.

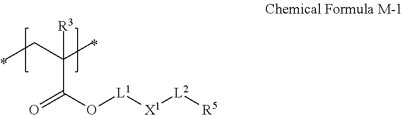

In Chemical Formula M-1,
R³ may be a hydrogen atom or a substituted or unsubstituted C1 to C10 alkyl group,
L¹ and L² may each independently be a single bond (e.g., a single covalent bond) or a substituted or unsubstituted C1 to C10 alkylene group,
X¹ may be a single bond (e.g., a single covalent bond), —O—, —S—, —S(═O)—, —S(═O)₂—, —C(═O)—, —C(═O)O—, —OC(═O)—, —OC(═O)O—, or —NR^{a}— (wherein, R^{a} may be a hydrogen atom, a deuterium atom, or a substituted or unsubstituted C1 to C10 alkyl group),
R⁵ may be a hydrogen atom, a fluorine atom, a hydroxyl group, or a substituted or unsubstituted C1 to C20 alkyl group,
at least one selected from among R⁵, L¹, and L² may include a fluorine atom and a hydroxyl group, and
* may be a linking point.

If (e.g., when) patterning a photoresist by exposing with EUV, the high energy of EUV photons may cause photon shot noise, which may result in deterioration of pattern dispersion, such as pattern roughness (e.g., LER and/or LWR) and/or IPU.

The resist topcoat composition according to one or more embodiments of the present disclosure may improve or enhance the sensitivity (e.g., the sensitivity of the photoresist during the photolithography micropattern formation process (e.g., the sensitivity capable of forming or providing a critical dimension (CD) of 50 nm)) as well as suppress pattern dispersion deterioration (or reduce a degree or occurrence of pattern dispersion deterioration) by increasing or enhancing the EUV absorption rate of a photoresist layer by introducing a compound including an iodine atom having high EUV absorption rate.

In one or more embodiments, the photoresist may be protected by including a polymer that includes a structural unit including a fluorine atom and/or a hydroxyl group that has little reactivity with the photoresist and may be well or suitably dissolved in a solvent, and the property of being well or suitably dissolved in a solvent makes it relatively easy to remove, thereby minimizing or reducing the influence on the photoresist.

In one or more embodiments, the photoresist topcoat composition according to one or more embodiments of the present disclosure may be coated on the top of the photoresist layer to significantly or substantially improve or enhance LER/LWR of L/S patterns, IPU of C/H patterns, and/or IPU of pillar patterns and also improve or enhance the sensitivity (e.g., the sensitivity of the photoresist during the photolithography micropattern formation process (e.g., the sensitivity capable of forming or providing a critical dimension (CD) of 50 nm)).

In one or more embodiments, the aromatic compound substituted with —I and —COOH may be represented by Chemical Formula 1.

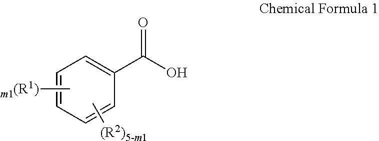

In Chemical Formula 1,
R¹ may be an iodine atom,
R² may be a hydrogen atom, a hydroxyl group, an iodine atom, a carboxyl group, or a substituted or unsubstituted C1 to C10 alkyl group, and
m1 may be one of integers of 1 to 5.

For example, m1 may be one of integers of 1 to 3.

For example, R² may be a hydrogen atom, a hydroxyl group, or an iodine atom.

For example, the aromatic compound substituted with —I and —COOH may be selected from among the compounds listed in Group I.

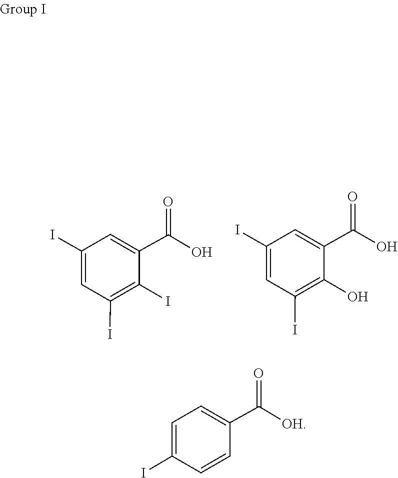

In one or more embodiments, the structural unit as represented by Chemical Formula M-1 may be represented by Chemical Formula 2.

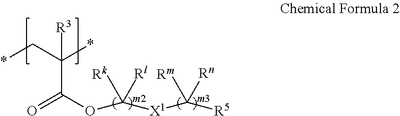

In Chemical Formula 2,
R³ may be a hydrogen atom or a substituted or unsubstituted C1 to C10 alkyl group,
R^{k}, R^{l}, R^{m}, Rⁿ, and R⁵ may each independently be a hydrogen atom, a fluorine atom, a hydroxyl group, or a substituted or unsubstituted C1 to C20 alkyl group,
m2 and m3 may each independently be one of integers of 1 to 10,
X¹ may be a single bond (e.g., a single covalent bond), —O—, —S—, —S(═O)—, —S(═O)₂—, —C(═O)—, —C(═O)O—, —OC(═O)—, —OC(═O)O—, or —NR^{a}— (wherein, R^{a} may be a hydrogen atom, a deuterium atom, or a substituted or unsubstituted C1 to C10 alkyl group), and
at least one selected from among R^{k}, R^{l}, R^{m}, Rⁿ, and R⁵ may include a fluorine atom and a hydroxyl group.

In Chemical Formula 2, if (e.g., when) m2 is 2 or more, each R^{k} may be substantially the same or different from each other.

In Chemical Formula 2, if (e.g., when) m2 is 2 or more, each R^{l} may be substantially the same or different from each other.

In Chemical Formula 2, if (e.g., when) m3 is 2 or more, each R^{m} may be substantially the same or different from each other.

In Chemical Formula 2, if (e.g., when) m3 is 2 or more, each Rⁿ may be substantially the same or different from each other.

In Chemical Formula 2, the expression that at least one selected from among R^{k}, R^{l}, R^{m}, Rⁿ, and R⁵ includes a fluorine atom and a hydroxyl group may refer to that:
at least one selected from among R^{k}, R^{l}, R^{m}, Rⁿ, and R⁵ is each independently a fluorine atom or a hydroxyl group, or
at least one selected from among R^{k}, R^{l}, R^{m}, Rⁿ, and R⁵ each independently includes a C1 to C10 alkyl group substituted with one or more fluorine atoms and a C1 to C10 alkyl group substituted with one or more hydroxyl groups, or
at least one selected from among R^{k}, R^{l}, R^{m}, Rⁿ, and R⁵ each independently includes one or more hydroxyl groups and one or more C1 to C10 alkyl groups substituted with a fluorine atom, or
at least one selected from among R^{k}, R^{l}, R^{m}, Rⁿ, and R⁵ each independently includes a C1 to C5 alkyl group substituted with one or more hydroxyl groups and one or more C1 to C5 fluoroalkyl groups, or
at least one selected from among R^{k}, R^{l}, R^{m}, Rⁿ, and R⁵ is a fluorine atom, and at least one selected from among the others is a hydroxyl group, or
at least one selected from among R^{k}, R^{l}, R^{m}, Rⁿ, and R⁵ is a fluorine atom, and at least one selected from among the others includes a C1 to C10 alkyl group substituted with one or more hydroxyl groups, or
at least one selected from among R^{k}, R^{l}, R^{m}, Rⁿ, and R⁵ is a hydroxyl group, and at least one selected from among the others includes a C1 to C10 alkyl group substituted with one or more fluorine atoms, or
at least one selected from among R^{k}, R^{l}, R^{m}, Rⁿ, and R⁵ is a C1 to C20 alkyl group substituted with one or more fluorine atoms, and at least one selected from among the others is a C1 to C20 alkyl group substituted with one or more hydroxyl groups.

For example, R³ may be a hydrogen atom or a methyl group,
X¹ may be a single bond (e.g., a single covalent bond), —O—, or —NR^{a}— (wherein, R^{a} may be a hydrogen atom, a deuterium atom, or a substituted or unsubstituted C1 to C10 alkyl group), and
R⁵ may be a fluorine atom, a hydroxyl group, a C1 to C10 alkyl group substituted with at least one fluorine atom, or a C1 to C10 alkyl group substituted with at least one hydroxyl group.

As an example, in Chemical Formula 2, at least one selected from among R^{m}, Rⁿ, and R⁵ may include a fluorine atom and a hydroxyl group.

For example, in Chemical Formula 2, at least one selected from among R^{m} and Rⁿ may be a fluorine atom or a C1 to C10 alkyl group substituted with at least one fluorine atom, and R⁵ may be a hydroxyl group or a C1 to C10 alkyl group substituted with at least one hydroxyl group.

For example, in Chemical Formula 2, at least one selected from among R^{m} and Rⁿ may be a hydroxyl group or a C1 to C10 alkyl group substituted with at least one hydroxyl group, and R⁵ may be a fluorine atom or a C1 to C10 alkyl group substituted with at least one fluorine atom.

For example, in Chemical Formula 2, R^{m} may be a hydroxyl group or a C1 to C10 alkyl group substituted with at least one hydroxyl group, Rⁿ may be a fluorine atom or a C1 to C10 alkyl group substituted with at least one fluorine atom, and R⁵ may be a hydroxyl group, a fluorine atom, or a C1 to C10 alkyl group substituted with at least one selected from among a fluorine atom and a hydroxyl group.

For example, in Chemical Formula 2, at least one selected from among R^{m} and Rⁿ may be a fluorine atom or a C1 to C10 alkyl group substituted with at least one fluorine atom, and R⁵ may be a hydroxyl group or a C1 to C5 alkyl group substituted with at least one selected from among a hydroxyl group and a C1 to C5 fluoroalkyl group.

For example, the structural unit as represented by Chemical Formula M-1 may be selected from the group listed in Group II.

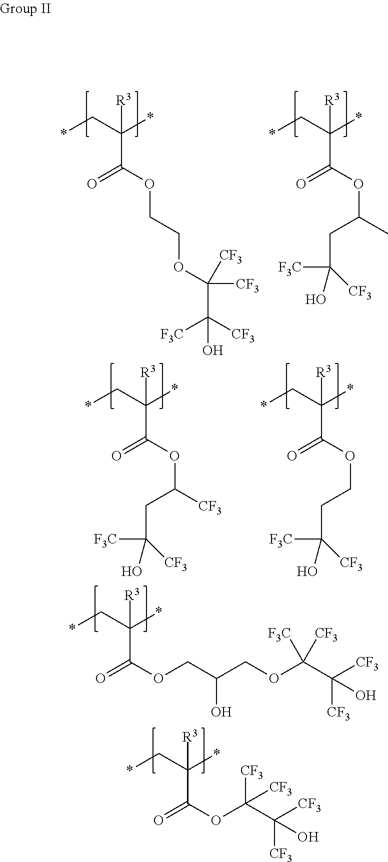

In Group II,
R³ may each independently be a hydrogen atom or a methyl group, and * is a linking point.

The polymer may further include an additional structural unit as represented by Chemical Formula M-2.

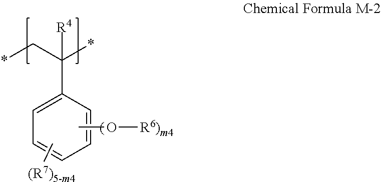

In Chemical Formula M-2,
R⁴ may be a hydrogen atom or a substituted or unsubstituted C1 to C10 alkyl group,
R⁶ may be a hydrogen atom or —C(═O)R^{d},
R^{d} may be a substituted or unsubstituted C1 to C10 alkyl group,
R⁷ may be a hydrogen atom, a halogen atom, a hydroxyl group, or a substituted or unsubstituted C1 to C10 alkyl group,
m4 may be one of integers of 1 to 4, and
* may be a linking point.

In Chemical Formula M-2, if (e.g., when) m4 is 2 or greater, each O—R⁶ may be substantially the same or different from each other.

In Chemical Formula M-2, if (e.g., when) 5-m4 is 2 or greater, each R⁷ may be substantially the same or different from each other.

For example, the additional structural unit may be represented by any one selected from among Chemical Formula 4-1 to Chemical Formula 4-4.

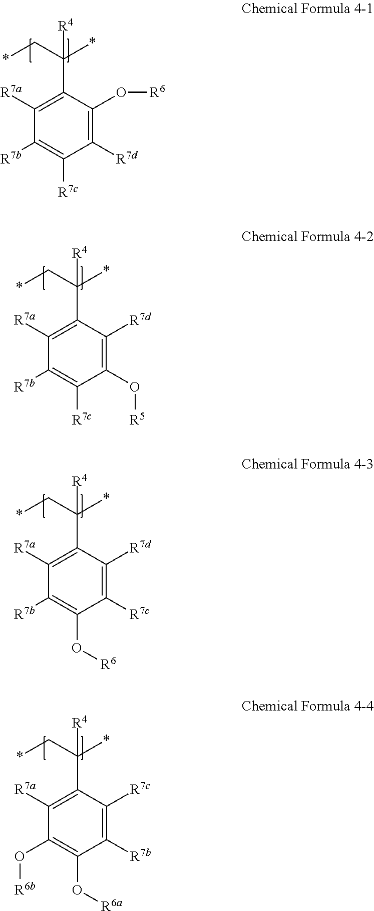

In Chemical Formula 4-1 to Chemical Formula 4-4,
R⁴ may be a hydrogen atom or a methyl group,
R⁶, R^{6a}, and R^{6b} may each independently be a hydrogen atom, or —C(═O)R^{d},
R^{d} may be a substituted or unsubstituted C1 to C5 alkyl group,
R^{7a}, R^{7b}, R^{7c}, and R^{7d} may each independently be a hydrogen atom, a halogen atom, a hydroxyl group, or a substituted or unsubstituted C1 to C10 alkyl group, and
* may be a linking point.

For example, at least one selected from among R⁷s may be a halogen atom.

For example, at least one selected from among R⁷s may be an iodine atom.

The sensitivity (e.g., the sensitivity of the photoresist during the photolithography micropattern formation process (e.g., the sensitivity capable of forming or providing a critical dimension (CD) of 50 nm)) may be further improved or enhanced by including an iodine atom in the additional structural unit.

For example, the additional structural unit may be selected from the group listed in Group III.

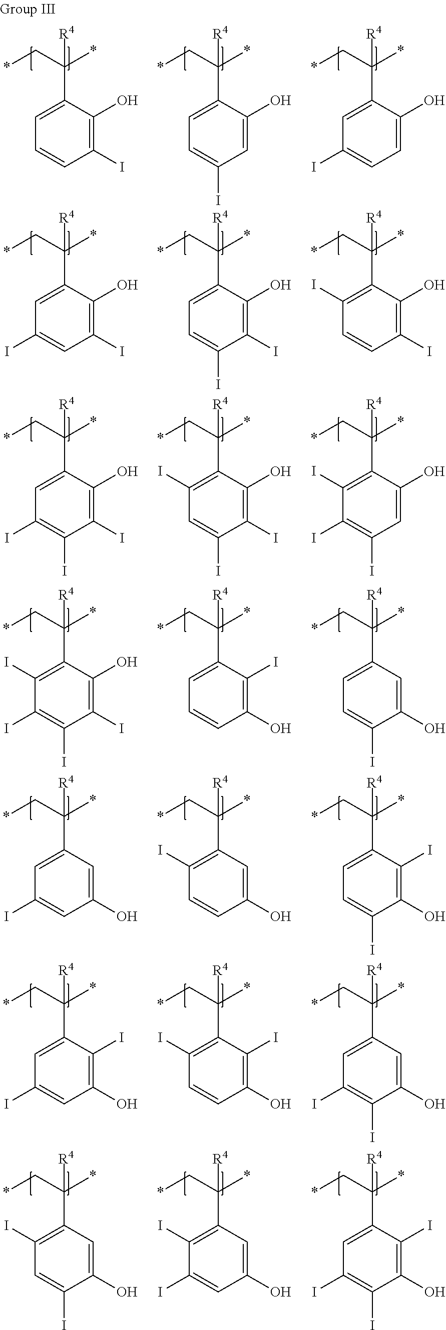

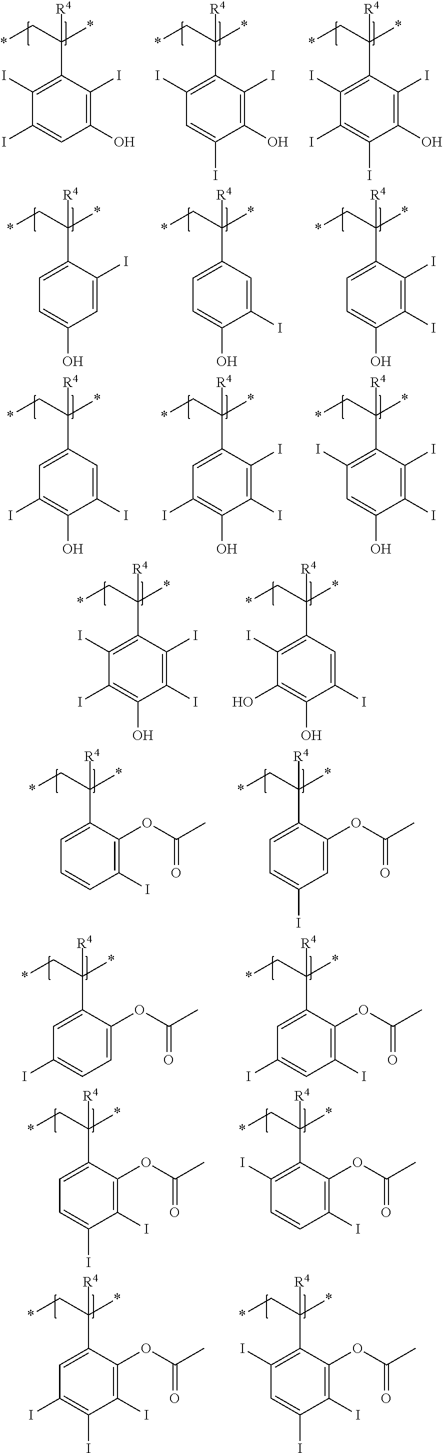

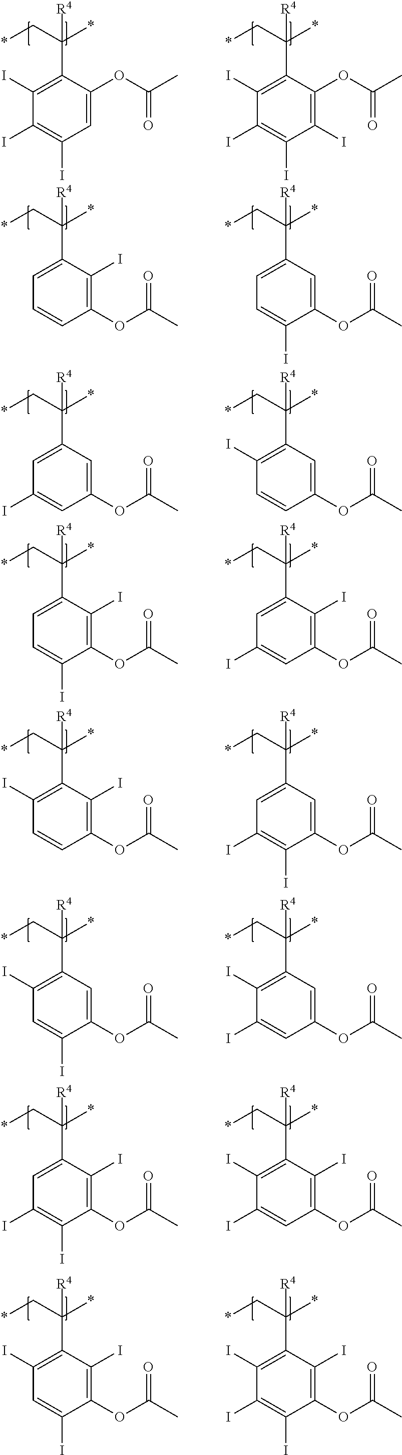

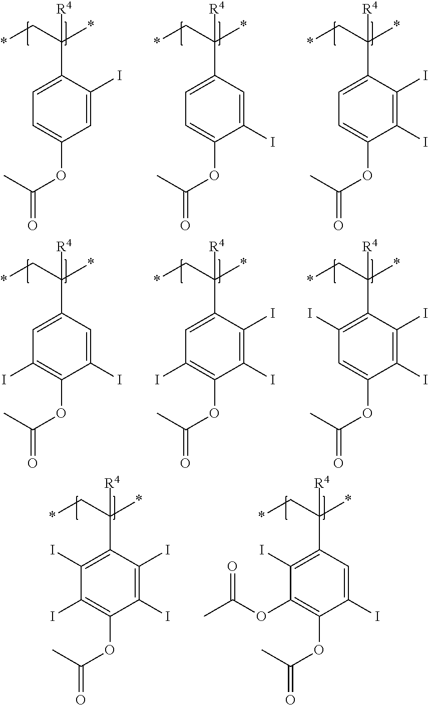

In Group III,
R⁴ may each independently be a hydrogen atom or a methyl group, and * may be a linking point.

The aromatic compound substituted with —I and —COOH may be included in an amount of about 0.1 wt % to about 3 wt % based on a total weight (e.g., based on 100 wt % of a total weight) of the resist topcoat composition.

The polymer may be included in an amount of about 0.1 wt % to about 10 wt % based on a total weight (e.g., based on 100 wt % of a total weight) of the resist topcoat composition.

For example, the polymer may be included in an amount of about 0.1 wt % to about 5 wt %, for example, about 0.1 wt % to about 3 wt %, based on a total weight (e.g., based on 100 wt % of a total weight) of the resist topcoat composition.

By being included in the foregoing ranges, the removal of the resist topcoat composition may be facilitated.

The polymer may include about 50 mol % to about 100 mol % of a structural unit as represented by Chemical Formula M-1.

For example, the polymer may include about 60 mol % to about 99 mol % or about 70 to about 95 mol % of the structural unit as represented by Chemical Formula M-1.

If (e.g., when) the molar ratios of structural units included in the polymer are within the foregoing ranges, the solubility of the polymer in organic solvents of the resist topcoat composition may be improved or enhanced and the pattern may be substantially uniformly coated.

The polymer may have a weight average molecular weight (M_{w}) of about 1,000 g/mol to about 50,000 g/mol. For example, the polymer may have a weight average molecular weight (M_{w}) of about 2,000 g/mol to about 30,000 g/mol, for example, about 3,000 g/mol to about 20,000 g/mol, or, for example, about 4,000 g/mol to about 10,000 g/mol, but embodiments of the present disclosure are not limited thereto. If (e.g., when) the weight average molecular weight (M_{w}) of the polymer is within the foregoing ranges, a carbon content (e.g., amount) and solubility of the polymer in a solvent (e.g., an organic solvent) of the resist topcoat composition including the polymer may be optimized or improved.

In one or more embodiments of the present disclosure, the structural unit of the polymer may be selected from among R¹ to R⁴ listed in Group IV, or the polymer of the present invention may be a copolymer may be selected from among R⁵ to R⁸ listed in Group IV.

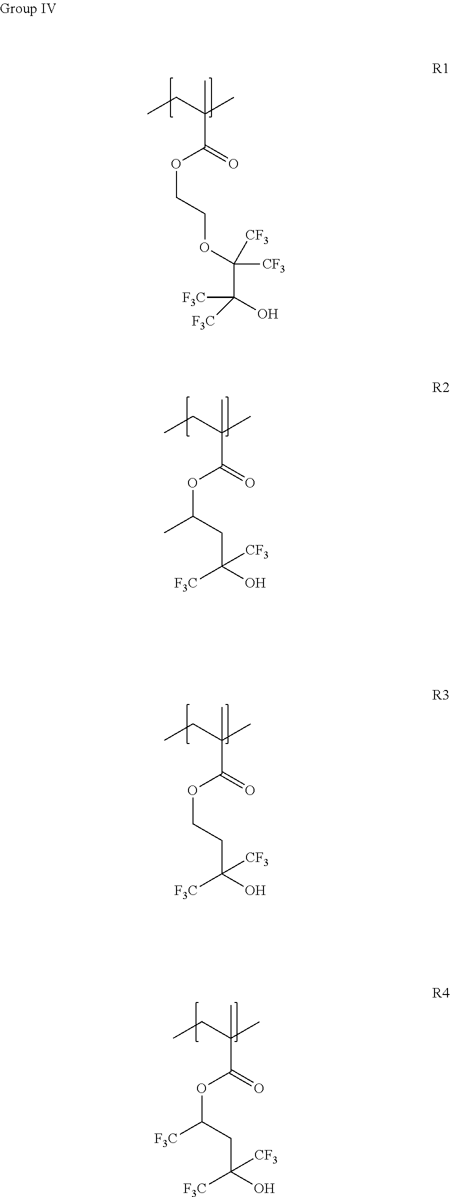

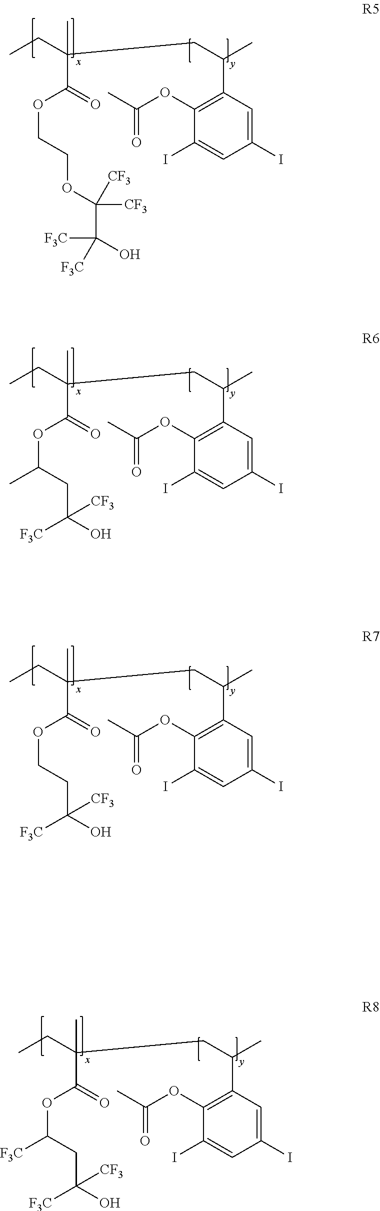

In Group IV, x:y may be 99:1 to 90:10.

In one or more embodiments, the resist topcoat composition may further include at least one other polymer selected from among an epoxy-based resin, a novolac resin, a glycoluril-based resin, and a melamine-based resin, but embodiments of the present disclosure are not limited thereto.

The resist topcoat composition may further include an additive including a surfactant, a thermal acid generator, a plasticizer, or a combination thereof.

The surfactant may be, for example, an alkylbenzene sulfonic acid salt, an alkylpyridinium salt, polyethylene glycol, a quaternary ammonium salt, and/or the like, but embodiments of the present disclosure are not limited thereto.

The thermal acid generator may be, for example, an acid compound, such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzoin tosylate, 2-nitrobenzyl tosylate, and/or other organic sulfonic acid alkyl esters, but embodiments of the present disclosure are not limited thereto.

The amount of these additives used may be easily adjusted according to the desired physical properties and may be omitted.

The solvent may be an ether-based solvent, and may be, for example, represented by Chemical Formula 5.

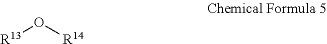

In Chemical Formula 5,

R¹³ and R¹⁴ may each independently be a substituted or unsubstituted C1 to C20 alkyl group or a substituted or unsubstituted C3 to C30 cycloalkyl group.

For example, the ether-based solvent may be selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, and a combination thereof.

The ether-based solvent may have sufficient or suitable solubility or dispersibility for the resist topcoat composition as described in one or more embodiments.

### Methods

In one or more embodiments, a method of forming or providing patterns by utilizing the photoresist topcoat composition as described in one or more embodiments may be provided. For example, the manufactured pattern may be a photoresist pattern.

A method of forming or providing patterns according to one or more embodiments of the present disclosure may include coating and heating a photoresist composition on a substrate to form or provide a photoresist layer, coating and heating the photoresist topcoat composition as described in one or more embodiments on the photoresist layer to form or provide a topcoat, and exposing and developing the topcoat and the photoresist layer to form or provide a resist pattern.

Hereinafter, a method of forming or providing patterns by utilizing the photoresist topcoat composition as described in one or more embodiments will be described with reference to the accompanying drawing. The accompanying drawing is a schematic view to illustrate a method of forming or providing patterns by utilizing a photoresist topcoat composition according to one or more embodiments of the present disclosure.

Referring to the accompanying drawing, an object 100 to be etched may be prepared. An example of the object to be etched may be a thin film formed or provided on a semiconductor substrate. Hereinafter, only the case where the object to be etched is a thin film will be described. The surface of the thin film may be cleaned to remove contaminants that remain on the thin film. The thin film may be, for example, a silicon nitride film, a polysilicon film, and/or a silicon oxide film.

A photoresist composition may be coated on the thin film and heated to form or provide a photoresist layer 101 (Step 1). Subsequently, the photoresist topcoat composition may be coated on the photoresist layer and heated to form or provide a photoresist topcoat 30 (Step 2).

The heating may be performed at a temperature of about 80° C. to about 500° C.

Then, the photoresist topcoat and the photoresist layer may be exposed to high-energy radiation.

For example, the high-energy radiation that may be used in the exposure process may include light having a high-energy wavelength, such as EUV (extreme ultraviolet; wavelength: 13.5 nm) and E-Beam (electron beam).

A post-exposure heat treatment (PEB) may be then performed. The post-exposure heat treatment may be performed at a temperature of about 80° C. to about 200° C. By performing the post-exposure heat treatment, the exposed region of the photoresist layer, for example, the region not covered by the patterned mask may be changed to a property that is soluble in a developer, so that the exposed region has a different solubility from that of the unexposed region of the photoresist layer.

A photoresist pattern 102b may be formed or provided by dissolving and removing the photoresist layer that corresponds to the exposed region and the photoresist topcoat using a developer (Step 3).

In one or more embodiments, the developer may be an alkaline developer and/or a developer containing an organic solvent (hereinafter referred to as an organic developer).

As the alkaline developer, a quaternary ammonium salt, such as tetramethylammonium hydroxide, may be used, but aqueous (e.g., water-soluble) alkaline solutions, such as inorganic alkalis, primary amines, secondary amines, tertiary amines, alcohol amines, and/or cyclic amines may also be used.

In one or more embodiments, the alkaline developer may include an alcohol and/or a surfactant in an appropriate or suitable amount. An alkaline concentration of the alkaline developer may be, for example, about 0.1 mass % to about 20 mass %, and a pH of the alkaline developer may be, for example, about 10 to about 15.

The organic developer may be a developer including at least one organic solvent selected from the group consisting of ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and/or the like.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and/or the like.

Solvents that are generally available or generally used may be used as alcohol solvents, amide solvents, ether solvents, and/or hydrocarbon solvents.

A plurality of the solvents may be mixed or may be mixed with solvents or water other than the solvents as described in one or more embodiments. A moisture content (e.g., amount) as a whole (e.g., based on 100% of a total amount) of the developer may be less than about 50 wt %, less than about 20 wt %, less than about 10 wt %, and, for example, the developer may be substantially free of moisture.

A content (e.g., amount) of the organic solvent may be about 50 wt % to about 100 wt %, about 80 wt % to about 100 wt %, about 90 wt % to about 100 wt %, or about 95 wt % to about 100 wt % based on a total amount (e.g., based on 100 wt % of a total amount) of the organic developer.

The organic developer may include an appropriate or suitable amount of a surfactant as described in one or more embodiments as desired or required.

A content (e.g., amount) of the surfactant may be about 0.001 wt % to about 5 wt %, about 0.005 wt % to about 2 wt %, or about 0.01 wt % to about 0.5 wt % based on a total amount (e.g., based on 100 wt % of a total amount) of the developer.

The organic developer may include the inhibitor as described in one or more embodiments.

The exposed thin film may be etched by applying the photoresist pattern as an etching mask. As a result, the thin film may be formed or provided into a thin film pattern.

The thin film may be etched, for example, by dry etching that utilizes an etching gas, and the etching gas may be, for example, CHF₃, CF₄, Cl₂, BCl₃, and a mixture thereof.

In the exposure process performed as described in one or more embodiments, the thin film pattern formed or provided by utilizing the photoresist pattern that is formed or provided by the exposure process performed by utilizing the EUV light source may have a width that correspond to the photoresist pattern. For example, the photoresist pattern may have a width of about 5 nm to about 100 nm. For example, the thin film pattern formed or provided by the exposure process performed by utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, for example, in a width of less than or equal to about 20 nm, like the photoresist pattern.

Hereinafter, the subject matter of the present disclosure will be described in more detail through examples that relate to the synthesis of the polymer as described in one or more embodiments and the preparation of a photoresist topcoat composition including the polymer. However, one or more embodiments of the present disclosure are not technically limited by the following examples.

### SYNTHESIS EXAMPLES

### (Synthesis of Polymer)

### Synthesis Example 1: Synthesis of Compound 1a

20 g of hexafluoro-2,3-bis(trifluoromethyl)-2,3-butanediol(perfluoropinacol), 7.79 g of 2-(hydroxyethyl)methacrylate, and 18.84 g of triphenylphosphine (Ph₃P) were mixed in 110 mL of diethyl ether under a nitrogen atmosphere and then, stirred. After the stirring for 30 minutes, the mixture was cooled down to 0° C., and another mixture of 14.52 g of diisopropyl azodicarboxylate (DIAD) and 35 mL of diethyl ether was slowly added thereto over 2 hours. Subsequently, the obtained mixture was stirred at room temperature (23° C.) for 24 hours and then, concentrated. The concentrated mixture was dissolved in dichloromethane and then, treated through column chromatography by using silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate as represented by Chemical Formula 1a.

¹H-NMR (Acetone-d6; ppm): δ1.90 (3H, t), 4.36 (4H, m), 5.63 (1H, t), 6.09 (1H, t), 8.34 (1H, s)

¹⁹F-NMR (Acetone-d6; ppm): δ −70.12 (6F, m), −65.38 (6F, m)

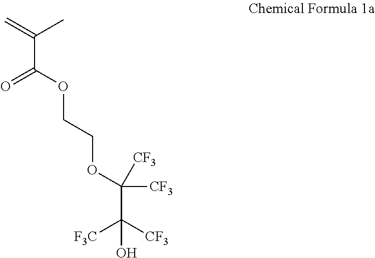 [SMILES: C=C(C)C(=O)OCCOC(C(F)(F)F)(C(F)(F)F)C(O)(C(F)(F)F)C(F)(F)F]

### Synthesis Example 2: Preparation of Polymer R1

16.1 g of a compound as represented by Chemical Formula 1a and 110 g of diisoamyl ether (DIAE) were added to a 250 mL 2-neck round bottom flask under a nitrogen atmosphere and then, heated to an internal temperature of 85° C. When the internal temperature reached 85° C., 14.7 g of a 25 wt % V-601/DIAE solution (V-601, 3.7 g) was slowly added thereto, and after 6 hours, the reaction solution was cooled to room temperature and then, concentrated to have a solid content (e.g., amount) of 50%. Subsequently, 270 g of heptane was added to the concentrated solution to filter a polymer produced therein. 34 g of the filtered polymer was completely dissolved in DIAE, and 270 g of heptane was added thereto for precipitation, which was twice repeated, and a precipitate obtained therefrom was completely dried to prepare Polymer R1 (M_{w}=5,000).

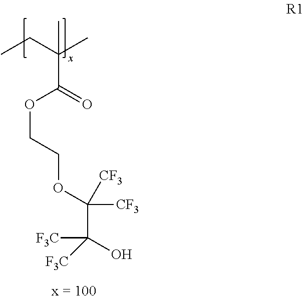

### Preparation of Resist Topcoat Compositions

### Example 1

0.98 g (0.5 wt %) of the polymer (R1) according to Synthesis Example 2 and 1.47 mg (0.15 wt %) of compound A1 (TCI Corporation) were dissolved in 199 g of a mixed solvent of DIAE/PGME (w/w=97/3) and then, stirred at room temperature (23° C.) for 24 hours and filtered with a Teflon™ (polytetrafluoroethylene) filter having a pore size of 0.45 μm to prepare a resist topcoat composition.

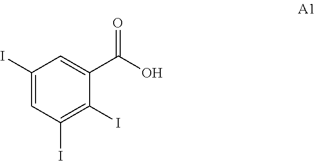 [SMILES: O=C(O)c1cc(I)cc(I)c1I]

### Examples 2 to 3, and Comparative Examples 1 to 5

Each resist topcoat composition was prepared in substantially the same manner as in Example 1 except that the types or kinds of polymers and compounds were changed as shown in Table 1.

### Evaluation 1: Solubility Evaluation

Each of the compositions according to Examples 1 to 3 and Comparative Examples 1 to 5 was stirred for 24 hours and examined with respect to presence or absence of precipitates with naked eyes, and the results are shown in Table 1. (absence of precipitation—solubility ∘, presence of precipitation—solubility X)

### Evaluation 2: Developability Evaluation

Each of the photoresist topcoat compositions prepared in Examples and Comparative Examples was spin-coated on a silicon substrate and heat-treated at 110° C. on a hot plate for 1 minute, to form or provide an about 5 nm-thick photoresist topcoat. The substrate with a topcoat formed or provided thereon was rinsed with 2.38% tetramethylammonium hydroxide aqueous solution and heat-treated again at 110° C. on the hot plate for 1 minute and then, measured with respect to a thickness change of the topcoat layer, and the results are shown in Table 1.

$${}^{*} Residual film after development ( \% ) = [ Topcoat thickness before development ( nm ) - Topcoat thickness after development ( nm ) ] \times 100 / Topcoat thickness before development ( nm )$$

$$Residual film after development \leq 20 \% - Developability O , \\ Topcoat thickness after development > 20 \% - Developability X$$

### Evaluation 3: Evaluation of Sensitivity and LWR

After forming or providing a resist underlayer (thickness: 50 Å) and a photoresist thin film for EUV (a thickness: 700 Å) on a 12-inch silicon substrate, each of the photoresist topcoat compositions according to Examples and Comparative Examples was spin-coated and then, heat-treated at 110° C. for 1 minute on a hot plate to form or provide about 5 nm-thick topcoats for photoresist.

On the wafer on which the photoresist topcoat film was formed or provided, a line & space pattern was formed or provided in a Focus-Energy Matrix (FEM) format by using an E-Beam equipment (JBX-9300FS, JEOL Inc.). Optimal sensitivity capable of forming or providing a critical dimension (CD) of 50 nm was confirmed in an interpolation method, and the results are shown in Table 1.

After confirming the optimal sensitivity, the line width roughness (LWR) dispersion was measured in the corresponding energy shot using Hitatchi's CD-SEM equipment. In order to increase the reliability of the dispersion value, substantially the same pattern of 500 points was measured within the shot, and the final average value is shown in Table 1.

TABLE 1

| | Poly- | | | Develop- | Sensitivity | LWR |
|---|---|---|---|---|---|---|
| | mer | Compound | Solubility | ability | (μC/cm²) | (nm) |
| Example 1 | R1 | A1 | O | O | 920 | 3.8 |
| Example 2 | R1 | A2 | O | O | 960 | 3.9 |
| Example 3 | R1 | A3 | O | O | 1030 | 4.0 |
| Comparative | R1 | — | O | O | 1210 | 4.3 |
| Example 1 | | | | | | |
| Comparative | R1 | A4 | O | X | 1170 | 4.1 |
| Example 2 | | | | | | |
| Comparative | R1 | A5 | O | X | 1180 | 4.2 |
| Example 3 | | | | | | |
| Comparative | R1 | A6 | O | X | 1185 | 4.2 |
| Example 4 | | | | | | |
| Comparative | R1 | A7 | O | O | 1200 | 4.3 |
| Example 5 | | | | | | |

A2: 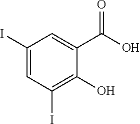 [SMILES: O=C(O)c1cc(I)cc(I)c1O]
(TCI Corporation)
A3: 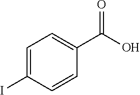
(TCI Corporation)
A4: 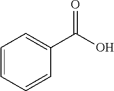
(TCI Corporation)
A5: 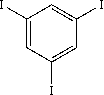
(Sigma-aldrich)
A6: 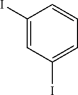
(Sigma-aldrich)
A7: 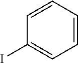
(Sigma-aldrich)

Referring to Table 1, when the resist topcoat composition according to one or more embodiments of the present disclosure was applied, excellent solubility and developability were not only maintained, but also the sensitivity was improved, but pattern degradation was suppressed, resultantly having an effect of improving LWR.

On the contrary, the resist topcoat composition according to Comparative Examples exhibited no LWR improvement effect and deteriorated the sensitivity.

On the other hand, in the case of the resist topcoat composition according to Comparative Examples, the LWR improvement effect was not observed or the sensitivity was reduced.

Hereinbefore, certain embodiments of the present disclosure have been described and illustrated, however, it should be apparent to a person having ordinary skill in the art that the present disclosure is not limited to the embodiments as described, and may be suitably modified and transformed without departing from the spirit and scope of the present disclosure. In one or more embodiments, the modified or transformed embodiments as such may not be understood separately from the technical ideas and aspects of one or more embodiments of the present disclosure, and the modified embodiments are within the scope of the appended claims and equivalents thereof of the present disclosure.

### REFERENCE NUMERALS

1: forming or providing a photoresist layer
2: forming or providing a photoresist topcoat
3: exposing and developing the photoresist layer and the photoresist topcoat to form or provide a resist pattern
30: photoresist topcoat
100: substrate
101: photoresist layer
102b: photoresist pattern

What is claimed is:

1. A resist topcoat composition, comprising:
an aromatic compound substituted with —I and —COOH;
a polymer comprising a structural unit as represented by Chemical Formula M-1; and
a solvent: 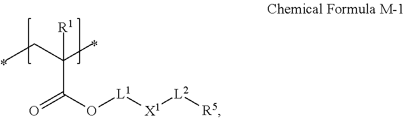
wherein, in Chemical Formula M-1,
R³ is a hydrogen atom or a substituted or unsubstituted C1 to C10 alkyl group,
L¹ and L² are each independently a single bond or a substituted or unsubstituted C1 to C10 alkylene group,
X¹ is a single bond, —O—, —S—, —S(═O)—, —S(═O)₂—, —C(═O)—, —C(═O)O—, —OC(═O), —OC(═O)O—, or —NR^{a}— (wherein, R^{a} is a hydrogen atom, a deuterium atom, or a substituted or unsubstituted C1 to C10 alkyl group),
R⁵ is a hydrogen atom, a fluorine atom, a hydroxyl group, or a substituted or unsubstituted C1 to C20 alkyl group,
at least one selected from among R⁵, L¹, and L² comprises a fluorine atom and a hydroxyl group, and
* is a linking point.

2. The resist topcoat composition as claimed in claim 1, wherein
the aromatic compound substituted with —I and —COOH is represented by Chemical Formula 1: 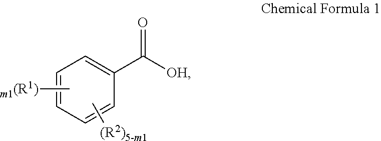
wherein, in Chemical Formula 1,
R¹ is an iodine atom,
R² is a hydrogen atom, a hydroxyl group, an iodine atom, a carboxyl group, or a substituted or unsubstituted C1 to C10 alkyl group, and
m1 is one of integers of 1 to 5.

3. The resist topcoat composition as claimed in claim 2, wherein
m1 is one of integers of 1 to 3.

4. The resist topcoat composition as claimed in claim 2, wherein
R² is a hydrogen atom, a hydroxyl group, or an iodine atom.

5. The resist topcoat composition as claimed in claim 1, wherein
the aromatic compound substituted with —I and —COOH is selected from among the compounds listed in Group I:

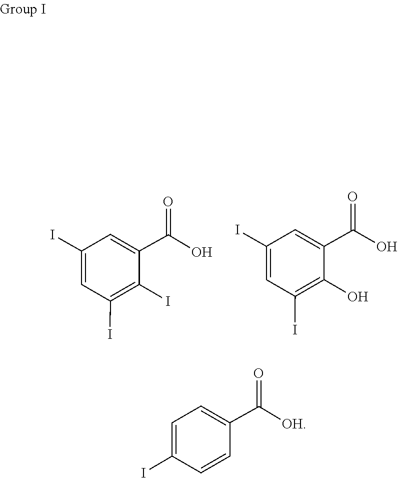

6. The resist topcoat composition as claimed in claim 1, wherein
the structural unit as represented by Chemical Formula M-1 is represented by Chemical Formula 2: 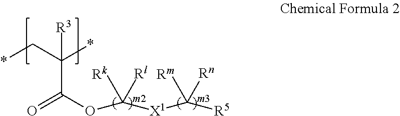
wherein, in Chemical Formula 2,
R³ is a hydrogen atom or a substituted or unsubstituted C1 to C10 alkyl group,
R^{k}, R^{l}, R^{m}, Rⁿ, and R⁵ are each independently a hydrogen atom, a fluorine atom, a hydroxyl group, or a substituted or unsubstituted C1 to C20 alkyl group,
m2 and m3 are each independently one of integers of 1 to 10,
X¹ is a single bond, —O—, —S—, —S(═O)—, —S(═O)₂—, —C(═O)—, —C(═O)O—, —OC(═O), —OC(═O)O—, or —NR^{a}— (wherein, R^{a} is a hydrogen atom, a deuterium atom, or a substituted or unsubstituted C1 to C10 alkyl group), and
at least one selected from among R^{k}, R^{l}, R^{m}, Rⁿ, and R⁵ comprises a fluorine atom and a hydroxyl group.

7. The resist topcoat composition as claimed in claim 1, wherein
the structural unit as represented by Chemical Formula M-1 is selected from the group listed in Group II: 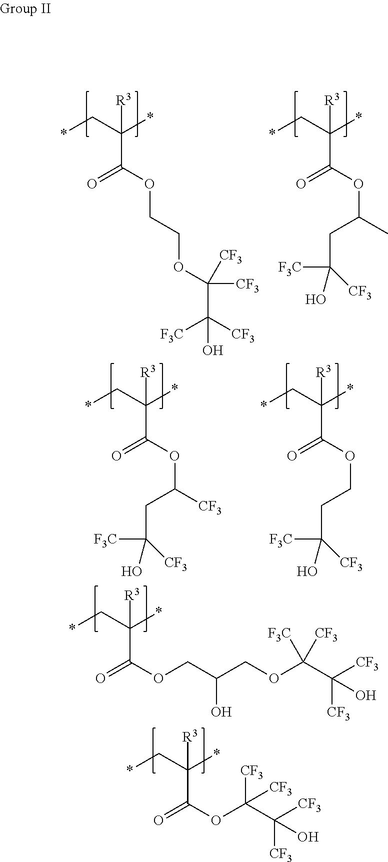
wherein, in Group II,
R³ are each independently a hydrogen atom or a methyl group, and * is a linking point.

8. The resist topcoat composition as claimed in claim 1, wherein
the polymer further comprises an additional structural unit as represented by Chemical Formula M-2: 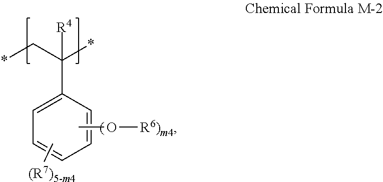
wherein, in Chemical Formula M-2,
R⁴ is a hydrogen atom or a substituted or unsubstituted C1 to C10 alkyl group,
R⁶ is a hydrogen atom or C(═O)R^{d},
wherein R^{d} is a substituted or unsubstituted C1 to C10 alkyl group,
R⁷ is a hydrogen atom, a halogen atom, a hydroxyl group, or a substituted or unsubstituted C1 to C10 alkyl group,
m4 is one of integers of 1 to 4, and
* is a linking point.

9. The resist topcoat composition as claimed in claim 8, wherein
the additional structural unit is represented by any one selected from among Chemical Formula 4-1 to Chemical Formula 4-4: 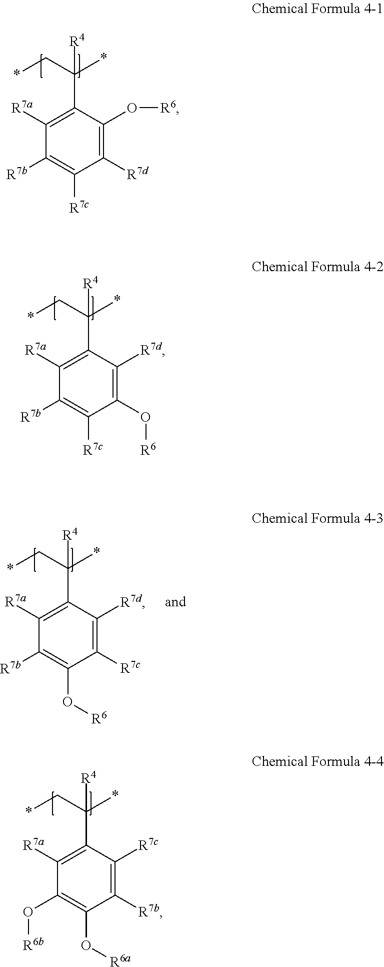
wherein, in Chemical Formula 4-1 to Chemical Formula 4-4,
R⁴ is a hydrogen atom or a methyl group,
R⁶, R^{6a}, and R^{6b} are each independently a hydrogen atom or C(═O)R^{d},
wherein R^{d} is a substituted or unsubstituted C1 to C5 alkyl group,
R^{7a}, R^{7b}, R^{7c}, and R^{7d} are each independently a hydrogen atom, a halogen atom, a hydroxyl group, or a substituted or unsubstituted C1 to C10 alkyl group, and
* is a linking point.

10. The resist topcoat composition as claimed in claim 8, wherein
the additional structural unit is at least one selected from the group listed in Group III: 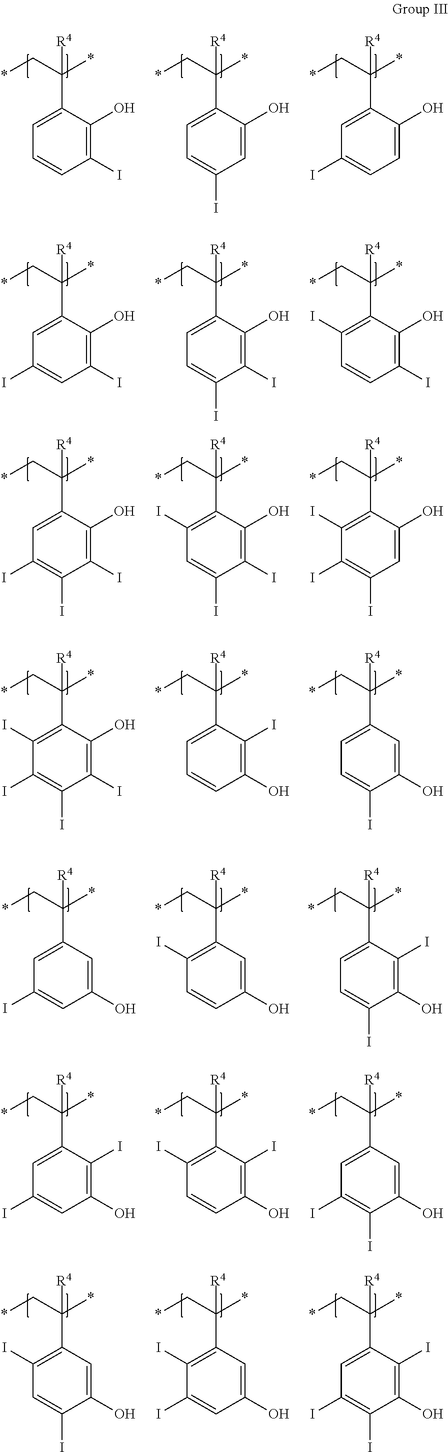 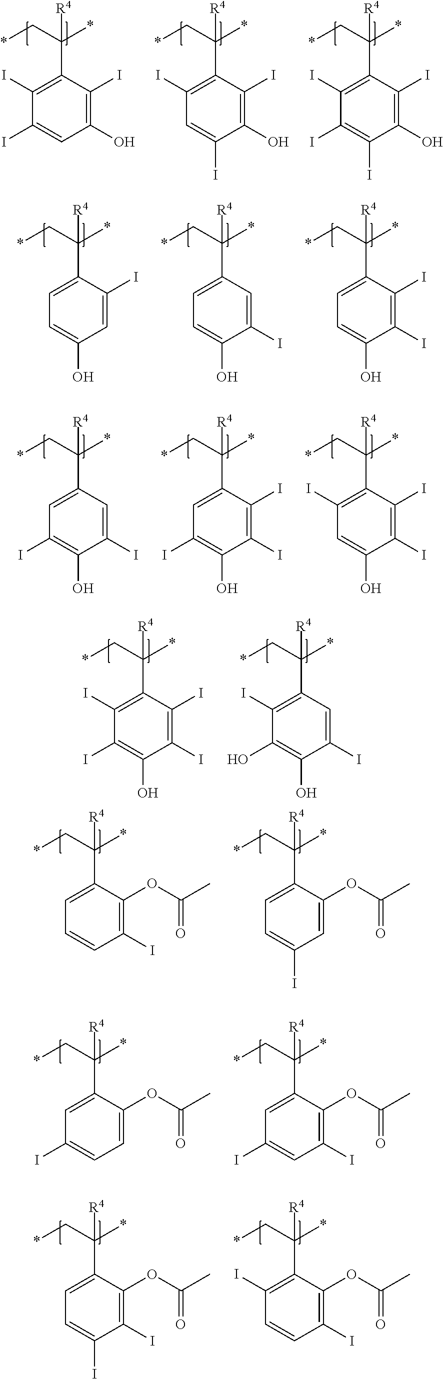 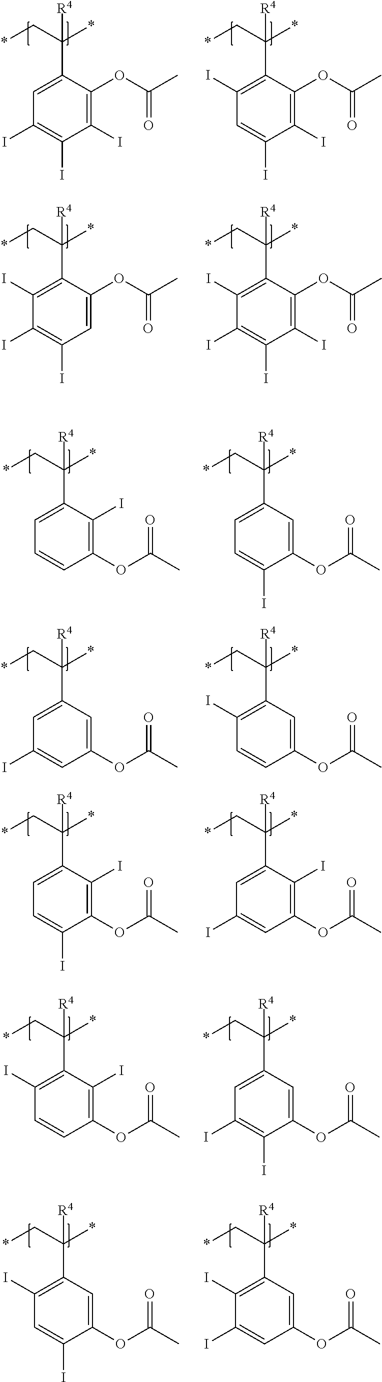 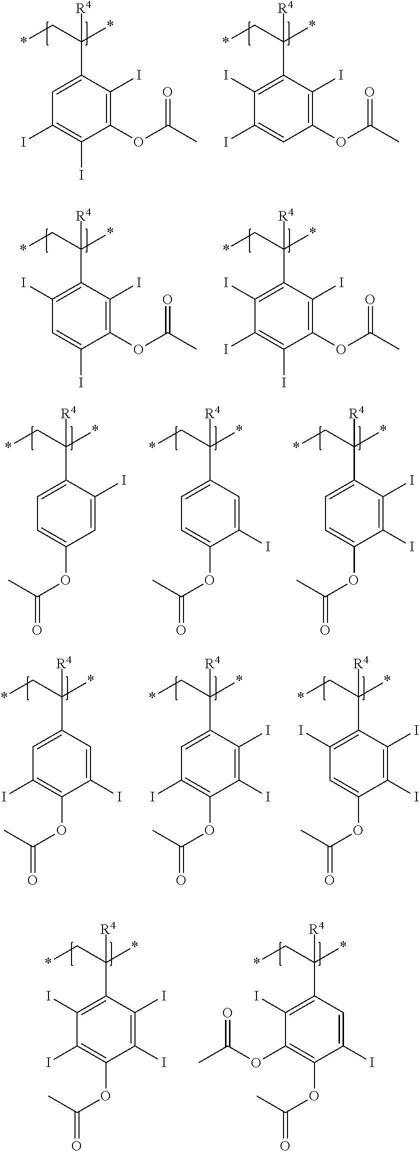
wherein, in Group III,
R⁴ are each independently a hydrogen atom or a methyl group, and * is a linking point.

11. The resist topcoat composition as claimed in claim 1, wherein
the aromatic compound substituted with —I and —COOH is included in an amount of about 0.1 wt % to about 3 wt % based on a total weight of the resist topcoat composition.

12. The resist topcoat composition as claimed in claim 1, wherein
the polymer is included in an amount of about 0.1 wt % to about 10 wt % based on a total weight of the resist topcoat composition.

13. The resist topcoat composition as claimed in claim 1, wherein
the polymer has a weight average molecular weight of about 1,000 g/mol to about 50,000 g/mol.

14. The resist topcoat composition as claimed in claim 1, wherein
the solvent is an ether-based solvent.

15. A method of providing patterns, comprising:
coating and heating a photoresist composition on a substrate to provide a photoresist layer,
coating and heating the resist topcoat composition as claimed in claim 1 on the photoresist layer to provide a topcoat, and
exposing and developing the topcoat and the photoresist layer to provide a resist pattern.
